(19) United States
(12) Patent Application Publication
(10) Pub. No.: US 2025/0232950 A1
(43) Pub. Date: Jul. 17, 2025

(54) METHOD FOR GENERATING WRITING DATA, WRITING DATA GENERATION APPARATUS, METHOD OF CHARGED-PARTICLE BEAM WRITING, CHARGED-PARTICLE BEAM WRITING APPARATUS, AND COMPUTER-READABLE RECORDING MEDIUM

(71) Applicant: NuFlare Technology, Inc., Yokohama-shi (JP)

(72) Inventors: Kenichi YASUI, Kawasaki-shi (JP); Yuko KAJIWARA, Yokohama-shi (JP)

(73) Assignee: NuFlare Technology, Inc., Yokohama-shi (JP)

(21) Appl. No.: 19/005,324

(22) Filed: Dec. 30, 2024

(30) Foreign Application Priority Data
Jan. 11, 2024 (JP) 2024-002701

(51) Int. Cl. H01J 37/302; G03F 7/20; H01J 37/304; H01J 37/317

(52) U.S. Cl. CPC H01J 37/3026; G03F 7/2059; H01J 37/304; H01J 37/3174; H01J 2237/30416; H01J 2237/31764

(57) ABSTRACT

In one embodiment, a writing data generating method is for generating writing data used in a charged-particle beam writing apparatus. The method includes generating, with respect to a graphical pattern included in design data, a plurality of divided curves by dividing a curve surrounding the graphical pattern such that the divided curves are smaller than or equal to a predetermined size, and calculating a plurality of control points for representation of each of the divided curves as a parametric curve, calculating a feature amount of a curved portion surrounded by the parametric curve and a line segment connecting a start point and an end point of the parametric curve out of the plurality of control points, and generating the writing data including positional information of the plurality of control points and the feature amount of the curved portion.

### CROSS REFERENCE TO RELATED APPLICATION

This application is based upon and claims benefit of priority from the Japanese Patent Application No. 2024-2701, filed on Jan. 11, 2024, the entire contents of which are incorporated herein by reference.

### FIELD

The present invention relates to a method for generating writing data, a writing data generation apparatus, a method of charged-particle beam writing, a charged-particle beam writing apparatus, and a computer-readable recording medium.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. So-called electron beam lithography technique, in which resist is exposed by an electron beam writing apparatus to form patterns, is used to produce high-precision original patterns.

In electron beam writing, a problem arises with influence of a so-called proximity effect. The proximity effect causes the dimensions of a pattern to vary due to back scattering electrons. A dose correction method is known as one of methods for correcting the proximity effect.

The dose correction method determines a dose position-by-position based on the size and density of a surrounding pattern of a beam irradiation position.

In the irradiation amount correction, an irradiation amount of back scattering is calculated. This back scattering is generated by causing a resist to be exposed again to an electron beam irradiated to a photomask and reflected by the mask. This calculation uses area information representing pattern information in a layout with, for example, meshes of 100 nm square, barycenter information, and the like. An electron beam writing apparatus calculates a coverage rate (area rate) and a barycenter of an input graphic for each mesh regions sectioned at a predetermined size.

When a curve included in the input graphic is represented as a high-dimensional parametric curve such as a cubic B-spline curve or a cubic Bezier curve, the amount of calculation increases in analytical calculation of the coverage rate or the barycenter compared to that of the related-art calculation of a polygon or a trapezoid. When the input graphic including a curve is approximated by a polygon, the coverage rate can be comparatively easily calculated. However, when accuracy in the approximation is increased, the number of apices of the approximate polygon increases. This arises a problem in that the amount of calculation increases similarly.

### BRIEF DESCRIPTION OF THE DRAWINGS

FIG. 1 schematically illustrates a multi-charged-particle beam writing apparatus according to an embodiment of the present invention.

FIG. 2 illustrates an example of representation of a curve surrounding a graphic as a parametric curve.

FIG. 3 illustrates an example of the area of a curved portion of a Bezier curve.

FIG. 4 illustrates an example of a data structure of the writing data.

FIG. 5 illustrates an example of a data structure of the writing data.

FIG. 6 illustrates an example of division of the curved portion of the Bezier curve.

FIG. 7 illustrates the position of a barycenter of the curved portion of the Bezier curve.

FIG. 8 illustrates the position of an approximate barycenter of the curved portion of the Bezier curve.

### DETAILED DESCRIPTION

In one embodiment, a writing data generating method is for generating writing data used in a charged-particle beam writing apparatus. The method includes generating, with respect to a graphical pattern included in design data, a plurality of divided curves by dividing a curve surrounding the graphical pattern such that the divided curves are smaller than or equal to a predetermined size, and calculating a plurality of control points for representation of each of the divided curves as a parametric curve, calculating a feature amount of a curved portion surrounded by the parametric curve and a line segment connecting a start point and an end point of the parametric curve out of the plurality of control points, and generating the writing data including positional information of the plurality of control points and the feature amount of the curved portion.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

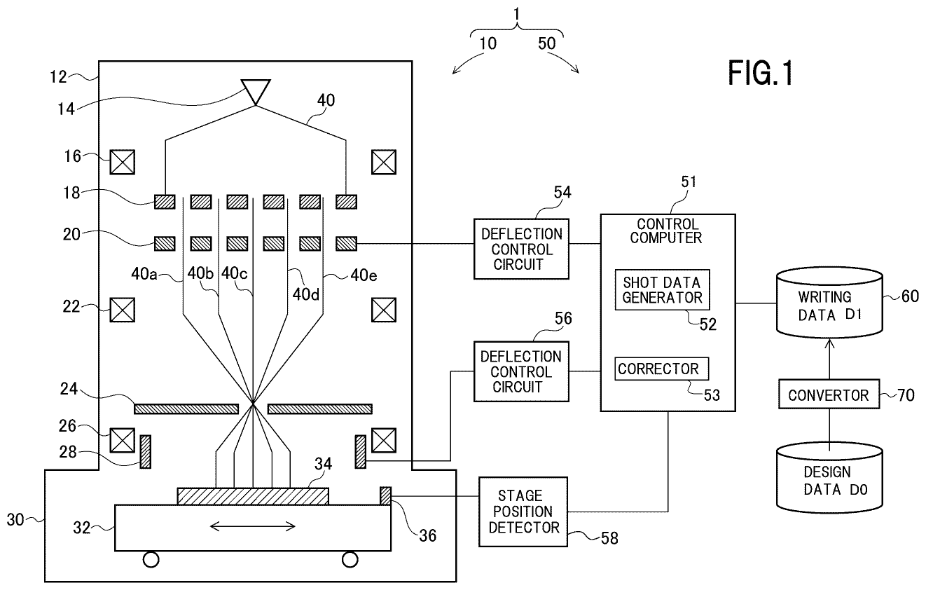

FIG. 1 schematically illustrates a multi-charged-particle beam writing apparatus 1 (hereinafter, referred to as a writing apparatus 1) configured to perform writing by using writing data according to an embodiment. The writing apparatus 1 includes a writing unit 10 and a control unit 50. The writing unit 10 is configured to irradiate a substrate 34 being a writing target such as a mask blank or a wafer with electron beams so as to write a desired pattern. The control unit 50 is configured to control a writing operation performed by the writing unit 10. The writing unit 10 includes an electron optical column 12 and a writing chamber 30.

The following components are disposed in the electron optical column 12: an electron source 14, an illumination lens 16, a shaping aperture array substrate 18, a blanking aperture array substrate 20, a reduction lens 22, a limiting aperture member 24, an objective lens 26, and a deflector 28. An XY stage 32 is disposed in the writing chamber 30. The substrate 34 being the writing target is placed on the XY stage 32. A mirror 36 for measuring the position of the XY stage 32 is also disposed on the XY stage 32.

The control unit 50 includes a control computer 51, deflection control circuits 54 and 56, and a stage position detector 58. The control computer 51, the deflection control circuits 54 and 56, and the stage position detector 58 are connected to each other via a bus.

An electron beam 40 discharged from the electron source 14 substantially perpendicularly illuminates the shaping aperture array substrate 18 by using the illumination lens 16. Openings are formed in the shaping aperture array substrate 18 in a matrix shape with a predetermined array pitch. The electron beam 40 illuminates a region where a plurality of (all) the openings of the shaping aperture array substrate 18 are included. When parts of the electron beam 40 respectively pass through the plurality of openings, multiple beams 40a to 40e as illustrated in FIG. 1 are formed.

Passage holes are formed in the blanking aperture array substrate 20 such that the passage holes are aligned with the positions where the respective openings of the shaping aperture array substrate 18 are disposed. Blankers are respectively disposed in the passage holes. The blankers each include two electrodes paired with each other. The electron beams 40a to 40e passing through the respective passage holes are independently deflected by voltages applied by the blankers and subjected to blanking control. Thus, a plurality of the blankers are configured to respectively perform blanking deflection on corresponding individual beams out of the multiple beams having passed through the plurality of openings of the shaping aperture array substrate 18.

The multiple beams 40a to 40e having passed through the blanking aperture array substrate 20 are reduced by the reduction lens 22 and travel toward an opening formed in the limiting aperture member 24. Here, the positions of individual beams deflected by the blankers of the blanking aperture array substrate 20 deviate from the opening of the limiting aperture member 24 and are shielded by the limiting aperture member 24. In contrast, individual beams not deflected by the blankers of the blanking aperture array substrate 20 pass through the opening of the limiting aperture member 24.

Thus, the limiting aperture member 24 shields the beams having been deflected so as to be set to a beam OFF state by using the blankers of the blanking aperture array substrate 20. The beams passing through the limiting aperture member 24 from when set to a beam ON state to when set to the beam OFF state serve as beams of a single shot. The multiple beams 40a to 40e having passed through the limiting aperture member 24 are focused by the objective lens 26 and become a pattern image of a desired reduction rate. The beams (the entirety of the multiple beams) having passed through the limiting aperture member 24 are collectively deflected in the same direction by the deflector 28 and irradiated to the substrate 34.

While the XY stage 32 is continuously moving, irradiation positions of the beams are controlled by the deflector 28 so as to follow the movement of the XY stage 32. The movement of the XY stage 32 is performed by using a stage control unit (not illustrated). The stage position detector 58 includes a laser interferometer configured to radiate laser to the mirror 36 and receive the reflected light. The stage position detector 58 detects the position of the XY stage 32 and notifies the stage control unit of the position of the XY stage 32.

The multiple beams irradiated at a time are ideally arranged with a pitch obtained by multiplying the array pitch of the plurality of openings of the shaping aperture array substrate 18 by the above-described desired reduction rate. The writing apparatus 1 is configured to perform the writing operation by using a raster scan method in which shot beams are continuously sequentially irradiated. When the desired pattern is written, beams required in accordance with the pattern are controlled to be set to the beam ON state under the blanking control.

The control computer 51 includes a shot data generator 52 and a corrector 53. The shot data generator 52 is configured to read writing data D1 from a storage device 60 and perform a data conversion process including a plurality of stages so as to generate device-unique shot data. In the shot data, an irradiation amount, the coordinates of the irradiation position, and the like of individual shots are defined. For example, the shot data generator 52 assigns a graphical pattern defined in the writing data to corresponding pixels (an irradiation unit region per beam of the multiple beams). Then, the shot data generator 52 calculates an area density ρ1 of the disposed graphical pattern for each pixel and calculate the irradiation amount (a dose amount) proportional to the area density. Specifically, the irradiation amount is computed as a value obtained by multiplying a preset reference irradiation amount D_{base} by a coefficient of proximity effect correction irradiation and the area density ρ1.

The coefficient of proximity effect correction irradiation is calculated by the corrector 53. The corrector 53 is configured to virtually divides a writing region of the substrate 34 into a plurality of mesh regions at a predetermined size (for example, about one tenth of an influence region of a proximity effect, about 100 nm), calculates an area density ρ of the graphical pattern disposed in each of the mesh regions, and calculates the coefficient of proximity effect correction irradiation for each of the mesh regions by using the area density ρ. The coefficient of proximity effect correction irradiation can be defined by a threshold model for proximity effect correction similar to the related-art technique, using a back scattering coefficient η, an irradiation amount threshold Dₜₕ of a threshold model, the area density ρ, and a distribution function.

The above-described reference irradiation amount D_{base} can be defined as follows: D_{base}=Dₜₕ/(1/2+η). An irradiation time of each of the pixels is calculated by dividing the irradiation amount of the pixel defined in the shot data by a current density. The deflection control circuit 54 is configured to transmit a blanking control signal based on the calculated irradiation time to the blanking aperture array substrate 20.

The present embodiment is to calculate, at high speed and with high accuracy, the area density ρ of the mesh regions for obtaining the coefficient of proximity effect correction irradiation.

First, a method for generating the writing data D1 is described. When a layout of a semiconductor integrated circuit is designed, design data (CAD data) DO to serve as layout data is generated and input to an input unit of a convertor 70. The convertor 70 (a writing data generation apparatus) performs a conversion process on the design data DO so as to generate the writing data D1 to be input to the control calculator 51 of the writing apparatus 1.

The design data DO includes a graphic surrounded by a curve (or including both a curve and a straight line). For a curved portion, the convertor 70 calculates a plurality of control points for representing a curve (representation as a parametric curve) to obtain information including the positions of the control points and the type of the curve. The convertor 70 generates the writing data D1 by sequentially defining pieces of positional information of the plurality of control points so as to rotate around the graphic once from a single apex (an origin of graphic disposition). The convertor 70 (the writing data generation apparatus) has the functions of a division processing unit, a control point calculation unit, a feature amount calculation unit, and a generation unit, which are to be described later. At least part of the convertor 70 may include hardware or software.

The division processing unit of the convertor 70 divides a curve surrounding the graphic such that divided curves are smaller than or equal to a size at which the writing region is divided into the mesh regions (the length of a single side of the mesh regions in the vertical or horizontal direction) in performing the above-described proximity effect correction computation. The control point calculation unit of the convertor 70 causes the curve having been divided (divided curve) to be represented as a parametric curve defined by four control points (the convertor 70 causes the divided curve to approximate the parametric curve). As a type of the parametric curve, for example, a curve for which terminal points (end points) of the control points are disposed on the divided curve such as a Bezier curve can be used.

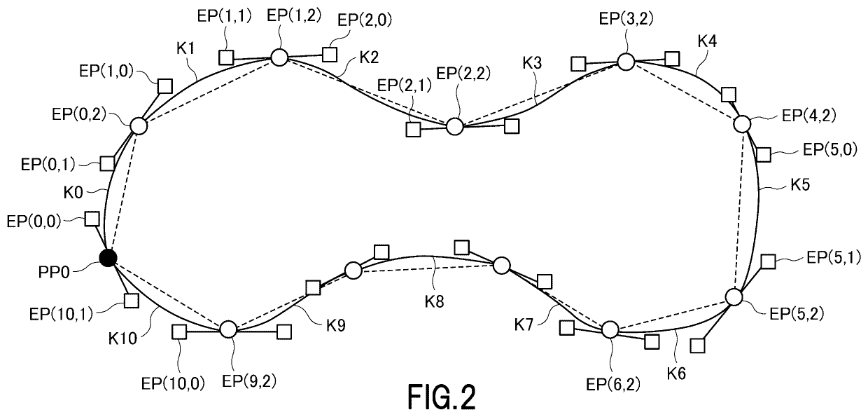

For example, as illustrated in FIG. 2, the divided curves are represented as cubic Bezier curves. In the example illustrated in FIG. 2, a curve surrounding the graphic (curve serving as the outline of the graphic) is represented as eleven Bezier curves K0 to K10.

The Bezier curve K0 is represented with four control points, PPO, EP (0, 0), EP (0, 1) and EP (0, 2). Out of four control points, two control points (terminal points), the start point PPO and the end point EP (0, 2), are positioned on the curve. The point PPO serves as the start point and the end point of the Bezier curve K10.

The Bezier curve K1 is represented with, four control points EP (0, 2), EP (1, 0), EP (1, 1) and EP (1, 2). Out of four control points, two control points (terminal points), the start point EP (0, 2) and the end point EP (1, 2), are positioned on the curve. The control point EP (0, 2) serves as the start point and the end point of the Bezier curve K0.

The Bezier curve K2 is represented with four control points, EP (1, 2), EP (2, 0), EP (2, 1) and EP (2, 2). Out of four control points, two control points (terminal points), the start point EP (1, 2) and the end point EP (2, 2), are positioned on the curve. The control point EP (1, 2) serves as the start point and the end point of the Bezier curve K1.

The Bezier curves K3 to K10 are represented similarly to the above description.

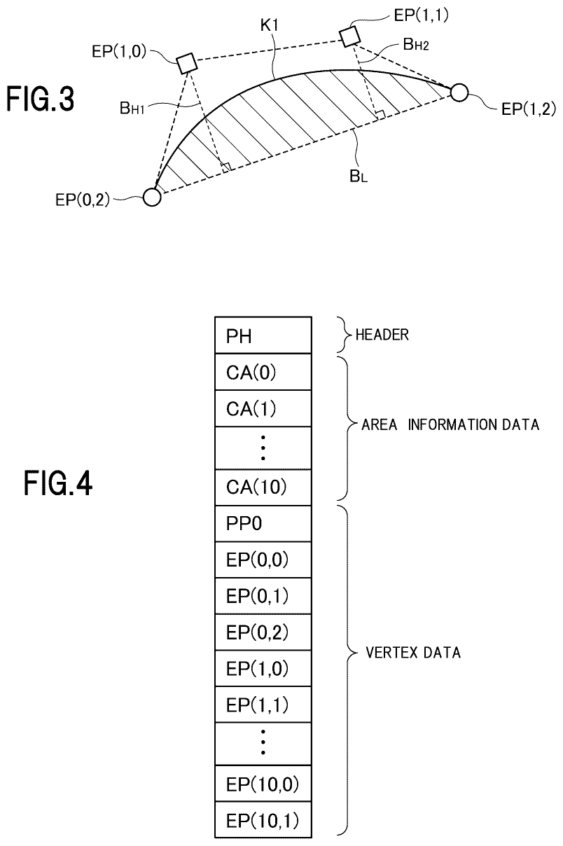

The feature amount calculation unit of the convertor 70 obtains the area of the curved portion as the feature amount of the curved portion for each of the Bezier curves. The area of the curved portion is the area of a region surrounded by the Bezier curve and a line segment connecting the terminal points (the start point and the end point) out of four control points to each other. For example, as illustrated in FIG. 3, an area CA (1) of the curved portion of the Bezier curve K1 is the area of a hatched portion in FIG. 3 surrounded by the Bezier curve K1 and a line segment B_{L} connecting the start point EP (0, 2) and the end point EP (1, 2) to each other. This area can be obtained by line integral with a formula of the Bezier curve and the Green's theorem.

Preferably, the curve surrounding the graphic is divided such that the length of the line segment B_{L} connecting the start point EP (0, 2) and the end point EP (1, 2) to each other, the length of a perpendicular B_{H1} from the control point EP (1, 0) to the line segment B_{L}, and the length of a perpendicular B_{H2} from EP (1, 1) to the line segment B_{L} are smaller than or equal to the mesh size in performing the proximity effect correction computation.

In the example illustrated in FIG. 2, areas CA (0) to CA (10) of the curved portions of the respective Bezier curves K0 to K10 are calculated.

The generation unit of the convertor 70 generates the writing data D1 including the positional information of the control points of all the Bezier curves with reference to the origin PPO and area information of the curved portions.

FIG. 4 illustrates an example of a data structure of the writing data D1. The writing data D1 includes a header PH, area information data, and vertex data. The header PH includes information of the number of apices, curve information, and the presence/absence of the area information. The information of the number of apices indicates the number of control points. In the example illustrated in FIG. 2, the number of control points is 33. The curve information indicates the number of dimensions and type of the parametric curves. The example illustrated in FIG. 2 is a cubic Bezier curve. The presence/absence of the area information indicates whether the area information data is included in the writing data D1.

As the area information data, the areas of the curved portions of the respective Bezier curves are sequentially defined. In the example illustrated in FIG. 2, the areas CA (0) to CA (10) of the curved portions of the respective Bezier curves K0 to K10 are sequentially defined.

As the vertex data, the positional information of the control points of the Bezier curves are defined sequentially from the origin of graphic disposition. In the example illustrated in FIG. 2, the positional information of EP (0, 0), EP (0, 1), EP (0, 2), EP (1, 0), EP (1, 1), EP (1, 2), and so forth are defined in a clockwise sequence from the origin PPO.

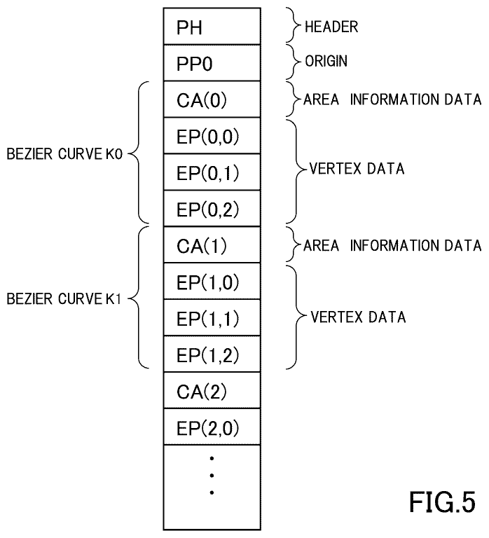

The data structure of the writing data D1 is not limited to that illustrated in FIG. 4. For example, as illustrated in FIG. 5, the positional information of the origin PPO may be described after a header part PH, and after that, the area information and information of the control points (three control points other than the start point) of each of the Bezier curves may be described. The start point of each of the Bezier curves is the end point of an immediately preceding Bezier curve.

Next, the proximity effect correction computation performed by the corrector 53 by using the writing data D1 having such a data structure is described.

The corrector 53 virtually divides the writing region of the substrate 34 into the plurality of mesh regions at a predetermined size (for example, about 100 nm) and calculates the area density ρ of the graphical pattern disposed in each of the mesh regions. When the graphical pattern has a shape surrounded by a curve as illustrated in FIG. 2, the area density of each of the mesh regions can be easily calculated by a known technique for a region other than the curved portions, that is, a polygonal region surrounded by the line segments connecting the start points and the end points of the Bezier curves K0 to K10 to each other. For example, the polygon is divided into triangles or trapezoids, and the area density of each of the mesh regions is calculated.

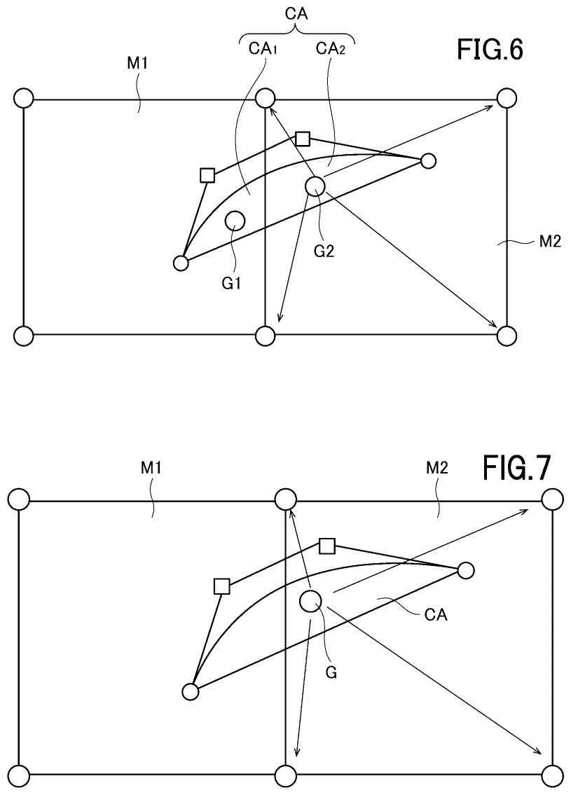

According to the related-art, when the curved portion CA of the Bezier curve extends over two adjacent mesh regions M1 and M2 as illustrated in FIG. 6, the curved portion CA is divided at a mesh boundary, a barycenter G1 and an area value of a curved portion CA₁ included in the mesh region M1 and a barycenter G2 and an area value of a curved portion CA₂ included in the mesh region M2 are calculated, and the area values are allocated to a plurality of apices of the mesh regions such that the position of the barycenter does not change in each of the mesh regions. For example, the area value of the curved portion CA₁ is allocated to four apices of the mesh region M1, and the area value of the curved portion CA₂ is allocated to four apices of the mesh region M2. However, there arises a problem in that a large amount of calculation is required to obtain the area and barycenter of each of the curved portions CA₁ and CA₂ divided at the mesh boundary, and thereby a writing processing time increases.

According to the present embodiment, as illustrated in FIG. 7, when the curved portion CA extends over two adjacent mesh regions M1 and M2, a barycenter G of the curved portion CA is obtained and the area value is allocated to a plurality of apices (four apices) of the mesh region in which the barycenter G is included (mesh region M2 in the example illustrated in FIG. 7) without dividing the curved portion CA at the mesh boundary. The area value is allocated such that an area barycenter position when the area values allocated to four apices are combined is coincident with the barycenter G. The area value of the curved portion CA, which is defined in the writing data D1, can be obtained at high speed. Since the curved portion CA is not divided at the mesh boundary, the amount of calculation can be reduced compared to that of the related-art technique illustrated in FIG. 6.

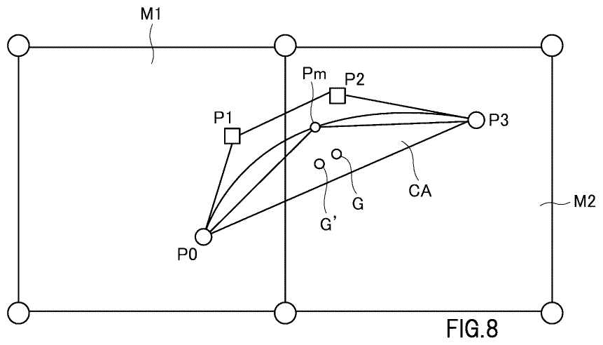

As illustrated in FIG. 8, instead of the barycenter G of the curved portion CA, a barycenter G′ of a triangle with the apices being the start point (t=0) and the end point (t=1) of the Bezier curve, and a middle point Pm (t=0.5) of the parameter may be calculated so as to allocate the area value to the plurality of apices of the mesh region M2 in which the barycenter G′ is included. By using coordinates P0 of the start point and coordinates P3 of the end point of the Bezier curve and coordinates P1 and P2 of two other control points, this barycenter G′ can be calculated by the following formula.

$${G}^{′} = ( 3 \times P 0 + P 1 + P 2 + 3 \times P 3 ) / 8$$

When the Bezier curve is smaller than or equal to the size of the mesh region (100 nm), the amount of a positional deviation between the barycenter G′ of the triangle and the barycenter G of the curved portion CA is about 10 nm at the maximum. Thus, a correction residual is significantly small, and accordingly, the barycenter G′ can be treated as an approximate barycenter of the curved portion CA. When the approximate barycenter G′ is obtained, the amount of calculation for obtaining the barycenter can be reduced.

For the curved portion of each of the Bezier curves, the corrector 53 calculates the barycenter G (or G′) and allocates the area value to the plurality of apices of the mesh region in which the barycenter G (or G′) is included. When barycenters G (or G′) of a plurality of curved portions are included in a single mesh region, allocated area values are cumulatively added to the apices of the mesh region.

The corrector 53 calculates the area value (area density ρ) of each of the mesh regions by using the area values that four apices of the mesh region have so as to obtain the coefficient of proximity effect correction irradiation.

Thus, according to the present embodiment, when the curved portion of the Bezier curve extends over two mesh regions, the area of the mesh can be calculated at high speed because of the allocation of the area value to the mesh region in which the barycenter is included. Furthermore, by approximating the barycenter of the curved portion of the Bezier curve to the barycenter of the triangle consisting of the start point, the end point and the middle point of the Bezier curve, the position of the barycenter can be obtained at high speed while degradation of accuracy is suppressed. Since the area of the curved portion of the Bezier curve is defined in the writing data D1, the area of the curved portion of the Bezier curve can be quickly obtained.

According to the above-described embodiment, the value of the area itself is defined as the area information of the curved portion of the Bezier curve in the writing data D1. However, instead of the area value, a value obtained by dividing the area by the length of the line segment connecting the start point and the end point may be defined. This can reduce the data amount of the area information. The control computer 51 calculates the length of the line segment connecting the start point and the end point from the coordinates of the start point and the end point of the Bezier curve defined in the writing data D1 and obtains the area value of the curved portion by multiplying the length of the line segment by the value defined in the area information.

The square root value of the area value may be defined as the area information of the curved portion of the Bezier curve in the writing data D1. This can reduce the data amount of the area information. The control computer 51 squares the value defined in the area information of the writing data D1 so as to obtain the area value of the curved portion.

According to the example explained in the above-described embodiment, the area of the curved portion is allocated to the mesh region in which the barycenter G (or the approximate barycenter G′) of the curved portion of the Bezier curve is included. However, regarding a plurality of mesh regions in which a quadrangle (part of a quadrangle) having apices being four control points of the Bezier curve is included, the areas of the quadrangle contained in the respective mesh regions may be obtained so as to allocate the area of the curved portion to the mesh regions depending on the rates of the obtained areas.

Alternatively, the area of the curved portion may be allocated as follows: a bounding box surrounding a quadrangle having apices being four control points of the Bezier curve is obtained; for a plurality of mesh regions in which the bounding box (or part of the bounding box) is included, the areas of bounding box contained in the respective mesh regions are obtained; and the area of the curved portion is allocated to the individual mesh regions depending on the rates of the areas of the bounding boxes.

The area of the curved portion of the Bezier curve defined in the writing data D1 may be the area of the triangle with the start point, the end point, and the middle point of the Bezier curve. Furthermore, instead of defining the area information in the writing data D1, the control computer 51 may calculate, from the vertex data, the area of the triangle with the start point, the end point, and the middle point of the Bezier curve.

According to the example explained in the above-described embodiment, the writing data D1 including the area information of the curved portion is generated. However, instead of the area information or in addition to the area information, the writing data D1 may include information of at least one of other feature amounts of the curved portion such as the barycenter, an edge length (the length of the Bezier curve), the curvature, a normal vector, and another arbitrary attribute value.

According to the example explained in the above-described embodiment, the divided curves are generated by dividing the curve surrounding the graphic such that the divided curves are smaller than or equal to the mesh size in performing the proximity effect correction computation. However, the divided curves may be generated by dividing the curve such that the divided curves are smaller than or equal to the size of the unit of correction (for example, the mesh size) in other correction computation than the proximity effect correction such as irradiation amount correction, graphical correction, or the like.

According to the example explained in the above-described embodiment, the writing data is generated by dividing the curve surrounding the graphic to have a size which is about the mesh size and causing the divided curve to approximate the parametric curve. However, the writing data may be generated without limiting the size of the parametric curve. In this case, the corrector 53 obtains, from the positional information of the control points of the Bezier curve, the length of the line segment B_{L}, the length of the perpendicular B_{H1}, and the length of the perpendicular B_{H2} as illustrated in FIG. 3. When all of these values are smaller than or equal to the mesh size, the corrector 53 calculates the approximate barycenter G′. When at least one of these values is greater than the mesh size, the corrector 53 analytically calculates the barycenter G.

Although a multi-beam irradiation apparatus that irradiates a large number of beams at a time by using multiple beams has been described in the above-described embodiment, a similar technique can be applied to a single beam irradiation apparatus that irradiates an irradiation target substrate with a single beam.

At least part of the control computer 51 described in the above embodiments may be implemented in either hardware or software. When implemented in software, a program that realizes at least part of functions of the control computer 51 may be stored on a recording medium such as a flexible disk or CD-ROM and read and executed by a computer. The recording medium is not limited to a removable recording medium such as a magnetic disk or optical disk, but may be a non-removable recording medium such as a hard disk device or memory.

The program that realizes at least part of the functions of the control computer 51 may be distributed through a communication line (including wireless communications) such as the Internet. Further, the program may be encrypted, modulated, or compressed to be distributed through a wired line or wireless line such as the Internet or to be distributed by storing the program on a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for generating writing data used in a charged-particle beam writing apparatus, the method comprising:
generating, with respect to a graphical pattern included in design data, a plurality of divided curves by dividing a curve surrounding the graphical pattern such that the divided curves are smaller than or equal to a predetermined size, and calculating a plurality of control points for representation of each of the divided curves as a parametric curve;
calculating a feature amount of a curved portion surrounded by the parametric curve and a line segment connecting a start point and an end point of the parametric curve out of the plurality of control points; and
generating the writing data including positional information of the plurality of control points and the feature amount of the curved portion.

2. The method for generating writing data according to claim 1,
wherein, in correction computation, the charged-particle beam writing apparatus virtually divides a writing region into a plurality of mesh regions, and
wherein the predetermined size is determined based on a size of the mesh regions in a horizontal direction or a vertical direction.

3. The method for generating writing data according to claim 1,
wherein the feature amount includes an area of the curved portion, a barycenter of the curved portion, an edge length of the curved portion, a curvature of the curved portion, a normal vector of the curved portion, or an arbitrary attribute value of the curved portion.

4. The method for generating writing data according to claim 1,
wherein the feature amount is a value obtained by dividing an area of the curved portion by a length of the line segment connecting the start point and the end point of the parametric curve.

5. The method for generating writing data according to claim 1,
wherein the start point and the end point of the parametric curve are positioned on the divided curve.

6. A writing data generation apparatus configured to generate writing data used in a charged-particle beam writing apparatus, the apparatus comprising:
an input unit configured to allow input of design data including a graphical pattern thereto;
a division processing unit configured to generate, with respect to the graphical pattern included in the design data having been input to the input unit, a plurality of divided curves by dividing a curve surrounding the graphical pattern such that the divided curves are smaller than or equal to a predetermined size;
a control point calculation unit configured to calculate a plurality of control points for representation of each of the divided curves as a parametric curve;
a feature amount calculation unit configured to calculate a feature amount of a curved portion surrounded by the parametric curve and a line segment connecting a start point and an end point of the parametric curve out of the plurality of control points; and
a generation unit configured to generate the writing data including positional information of the plurality of control points and the feature amount of the curved portion.

7. A computer-readable recording medium having stored therein a program for causing a computer to execute a process for generating writing data used in a charged-particle beam writing apparatus, the process comprising:
generating, with respect to a graphical pattern included in design data, a plurality of divided curves by dividing a curve surrounding the graphical pattern such that the divided curves are smaller than or equal to a predetermined size, and calculating a plurality of control points for representation of each of the divided curves as a parametric curve;
calculating a feature amount of a curved portion surrounded by the parametric curve and a line segment connecting a start point and an end point of the parametric curve out of the plurality of control points; and
generating the writing data including positional information of the plurality of control points and the feature amount of the curved portion.

8. A method of charged-particle beam writing, the method comprising:
reading, with respect to a graphical pattern to be written, the graphical pattern being surrounded by a plurality of parametric curves, writing data including positional information of control points of each of the plurality of parametric curves and area information of a curved portion surrounded by the parametric curve and a line segment connecting a start point and an end point of the parametric curve from a storage device;
virtually dividing a writing region into a plurality of mesh regions at a predetermined size, and, by using the writing data, calculating area values of the graphical pattern disposed in the respective mesh regions; and
calculating, by using the area values, an irradiation amount of a charged-particle beam for which a proximity effect is corrected,
wherein an area value of the curved portion is allocated to a mesh region including a barycenter of the curved portion out of the mesh regions.

9. The method of charged-particle beam writing according to claim 8,
wherein, as the barycenter of the curved portion, a barycenter of a triangle having apices being a start point of the parametric curve, an end point of the parametric curve, and a middle point of a parameter is calculated.

10. The method of charged-particle beam writing according to claim 8,
wherein a writing target substrate is irradiated with a charged-particle beam at the irradiation amount of the charged-particle beam so as to write a pattern.

11. A charged-particle beam writing apparatus,
wherein the charged-particle beam writing apparatus is configured to
read, with respect to a graphical pattern to be written, the graphical pattern being surrounded by a plurality of parametric curves, from a storage device writing data including positional information of control points of each of the plurality of parametric curves and area information of a curved portion surrounded by the parametric curve and a line segment connecting a start point and an end point of the parametric curve,
virtually divide a writing region into a plurality of mesh regions at a predetermined size, and, by using the writing data, calculate area values of the graphical pattern disposed in the respective mesh regions, and
calculate, by using the area values, an irradiation amount of a charged-particle beam for which a proximity effect is corrected, and
wherein the charged-particle beam writing apparatus includes a corrector configured to allocate an area value of the curved portion to a mesh region including a barycenter of the curved portion out of the mesh regions.

12. A charged-particle beam writing method comprising:
reading, with respect to a graphical pattern to be written, the graphical pattern being surrounded by a plurality of parametric curves, writing data including positional information of control points of each of the plurality of parametric curves and area information of a curved portion surrounded by the parametric curve and a line segment connecting a start point and an end point of the parametric curve from a storage device;
virtually dividing a writing region into a plurality of mesh regions at a predetermined size, and, by using the writing data, calculating area values of the graphical pattern disposed in the respective mesh regions; and
calculating, by using the area values, an irradiation amount of a charged-particle beam for which a proximity effect is corrected, and
wherein, when the curved portion extends over a plurality of the mesh regions, a quadrangle having apices being control points of the parametric curve corresponding to the curved portion or a bounding box surrounding the quadrangle is obtained, and an area value of the curved portion is allocated to a plurality of mesh regions in which the quadrangle or the bounding box is contained depending on rates of areas of the quadrangle or the bounding box corresponding to the respective mesh regions.

13. A charged-particle beam writing apparatus,
wherein the charged-particle beam writing apparatus is configured to
read, with respect to a graphical pattern to be written, the graphical pattern being surrounded by a plurality of parametric curves, writing data including positional information of control points of each of the plurality of parametric curves and area information of a curved portion surrounded by the parametric curve and a line segment connecting a start point and an end point of the parametric curve from a storage device,
virtually divides a writing region into a plurality of mesh regions at a predetermined size, and, by using the writing data, calculates area values of the graphical pattern disposed in the respective mesh regions, and
calculates, by using the area values, an irradiation amount of a charged-particle beam for which a proximity effect is corrected, and
wherein the charged-particle beam writing apparatus includes a corrector configured to
obtain a quadrangle having apices being control points of the parametric curve corresponding to the curved portion or a bounding box surrounding the quadrangle, and
allocate an area value of the curved portion to a plurality of mesh regions in which the quadrangle or the bounding box is contained depending on rates of areas of the quadrangle or the bounding box contained in the mesh regions.
